(19) United States
(12) Patent Application Publication
(10) Pub. No.: US 2025/0151419 A1
(43) Pub. Date: May 8, 2025

(54) PHOTOVOLTAIC MODULE ASSEMBLY WITH OPTIMISED QUANTITY OF ELECTRICALLY CONDUCTIVE ADHESIVE

(71) Applicants: COMMISSARIAT A L'ENERGIE ATOMIQUE ET AUX ENERGIES ALTERNATIVES, Paris (FR); 3SUN S.R.L, Catania (IT)

(72) Inventors: Romain SOULAS, Grenoble Cedex (FR); Vincent BARTH, Grenoble Cedex (FR); Corentin LUCAS, Grenoble Cedex (FR); Antonino RAGONESI, Catania (IT); Lorenzo CARBONE, Roma (IT)

(73) Assignees: COMMISSARIAT A L'ENERGIE ATOMIQUE ET AUX ENERGIES ALTERNATIVES, Paris (FR); 3SUN S.R.L, Catania (IT)

(21) Appl. No.: 18/934,314

(22) Filed: Nov. 1, 2024

(30) Foreign Application Priority Data
Nov. 2, 2023 (FR) 2311943

(51) Int. Cl. H01L 31/05

(52) U.S. Cl. CPC H10F 19/904; H10F 19/906

(57) ABSTRACT

An assembly including at least one photovoltaic cell including a face on which a collecting grid is arranged, at least one interconnection strip attached to the face, and intended to electrically and mechanically connect the photovoltaic cell to another photovoltaic cell, and at least one line of adhesive, made of an electrically conductive material, disposed between the collecting grid and the interconnection strip, the line of adhesive being adapted to mechanically and electrically connect the interconnection strip to the photovoltaic cell, the line of adhesive extending substantially along a main longitudinal axis (X) and having a substantially constant width. The line of adhesive is disposed according to a zigzag pattern formed from a plurality of segments each forming an angle (α) less than or equal to 30° with the main longitudinal axis (X).

### TECHNICAL FIELD

The invention relates to the field of photovoltaic modules, which include an assembly of photovoltaic cells interconnected electrically, and more specifically, to the interconnection of the photovoltaic cells.

The invention may be implemented for numerous applications, in particular civilian and/or military, for example standalone and/or embedded applications. It may thus in particular be applied for buildings such as homes or industrial premises (tertiary, commercial, etc.), for example for producing their roofing, for designing street furniture, for example for public lighting, road signage or charging electric cars, or also be used for mobile applications (solar mobility), in particular for integration on vehicles, such as cars, buses or boats, drones, dirigible balloons, inter alia.

### PRIOR ART

A photovoltaic module is formed from chains or arrays, more commonly referred to as strings, which are an assembly of several photovoltaic cells connected in series and/or in parallel by interconnection strips, for example tin-coated copper strips.

The interconnection strip may be connected electrically and mechanically to a photovoltaic cell by welding or by bonding with an electrically conductive adhesive (ECA).

The use of an electrically conductively adhesive is preferred on account of the high sensitivity of photovoltaic cells, in particular heterojunction cells, to temperature. Indeed, the polymerization temperature of electrically conductive adhesive is particularly low, for example of the order of 160° C. to 180° C. It is thus lower than the temperature used during welding, which may be of the order of 260° C. to 280° C.

Electrically conductive adhesive comprises conductive particles, typically silver particles. Hence, its use consumes silver, the resources of which are limited, and is relatively costly.

Several known solutions thus propose reducing the consumption of electrically conductive adhesive for the electrical and mechanical connection of an interconnection strip to a photovoltaic cell.

These solutions propose depositing the adhesive in the form of a continuous or dotted straight line, as shown in particular by the article by Kaiser et al. entitled Reduction of ECA amount for the ribbon interconnection of heterojunction solar cells, 37th European PV Solar Energy Conference and Exhibition, 7-11 Sep. 2020, the dimensions (width, length) of which are similar to those of the interconnection strip.

These solutions require that the line of adhesive and the interconnection strip be perfectly aligned to obtain a maximum contact surface area and ensure satisfactory adhesion of the interconnection strip on the photovoltaic cell.

However, the deposition of the electrically conductive adhesive and/or the interconnection strip may be associated with a positioning uncertainty, which is in particular associated with the precision of the equipment used for deposition. In the solutions described, such an uncertainty may then result in a misalignment of the adhesive and the interconnection strip, and may thus reduce the adhesion of the interconnection strip on the photovoltaic cell.

### DISCLOSURE OF THE INVENTION

The aim of the invention is that of remedying at least in part the drawbacks of the prior art, and more particularly that of providing a solution for improving the adherence of an interconnection strip on a photovoltaic cell, in particular when the interconnection strip and the line of adhesive are misaligned, while limiting the consumption of electrically conductive adhesive.

For this purpose, the subject matter of the invention is an assembly comprising:
at least one photovoltaic cell comprising a face on which a collecting grid is arranged,
at least one interconnection strip attached to said face, said interconnection strip being intended to electrically and mechanically connect the photovoltaic cell to another photovoltaic cell, and
at least one line of adhesive, made of an electrically conductive material, disposed between the collecting grid and the interconnection strip, the line of adhesive being adapted to mechanically and electrically connect the interconnection strip to the photovoltaic cell, the line of adhesive extending substantially along a main longitudinal axis and having a substantially constant width.

According to the invention, the line of adhesive is disposed according to a zigzag pattern formed from a plurality of segments each forming an angle less than or equal to 30° with the main longitudinal axis, and with an amplitude of variation, along a transverse axis perpendicular to the main longitudinal axis, which is greater than the width of the line of adhesive.

Some preferred, yet non-limiting, aspects of this assembly are as follows.

The angle formed by the segments with the main longitudinal axis may be between 15° and 30°.

A ratio between the amplitude of variation of the line of adhesive and a width of the interconnection strip may be between 0.5 and 1.5.

The width of the interconnection strip may be between 0.2 mm and 1.2 mm.

The line of electrically conductive adhesive may be made of a material chosen from among adhesives comprising conductive particles, for example silver and/or copper particles, carbon nanotubes or silver nanowires, or a polymer matrix, for example of acrylate, epoxy or silicone type.

### BRIEF DESCRIPTION OF THE DRAWINGS

Other aspects, aims, advantages and features of the invention will appear better upon reading the following detailed description of preferred embodiments thereof, given as a non-limiting example, and made with reference to the appended drawings wherein:

FIG. 1 represents schematically and partially, according to a top view, an assembly according to an embodiment of the invention, including a photovoltaic cell, interconnection strips and lines of electrically conductive adhesive disposed between the photovoltaic cell and a respective interconnection element;

FIG. 2 shows one of the lines of electrically conductive adhesive of FIG. 1 taken separately;

FIGS. 3A and 3B show an interconnection strip disposed on a line of adhesive with no misalignment, with a thin straight line of adhesive (FIG. 3A) and with a line of adhesive similar to that of FIG. 2 (FIG. 3B);

FIGS. 4A and 4B show an interconnection strip disposed on a line of adhesive with a misalignment, with the thin straight line of adhesive (FIG. 4A) and with a line of adhesive similar to that of FIG. 2 (FIG. 4B);

FIGS. 5A and 5B show an interconnection strip disposed on a line of adhesive with no misalignment, with a wide straight line of adhesive (FIG. 5A) and with a line of adhesive similar to that of FIG. 2 (FIG. 5B); and

FIGS. 6A and 6B show an interconnection strip disposed on a line of adhesive with a misalignment, with the wide straight line of adhesive (FIG. 6A) and with a line of adhesive similar to that of FIG. 2 (FIG. 6B).

### DETAILED DISCLOSURE OF PARTICULAR EMBODIMENTS

In the figures and in the following description, the same references represent identical or similar elements. In addition, the different elements are not plotted to scale so as to favor clarity of the figures. Moreover, the different embodiments and variants are not exclusive of one another and could be combined together. Unless stated otherwise, the terms “substantially”, “about”, “in the range of” mean within a 10% margin, and preferably within a 5% margin. Moreover, the terms “comprised between . . . and . . . ” and the like mean that the bounds are not included, unless stated otherwise.

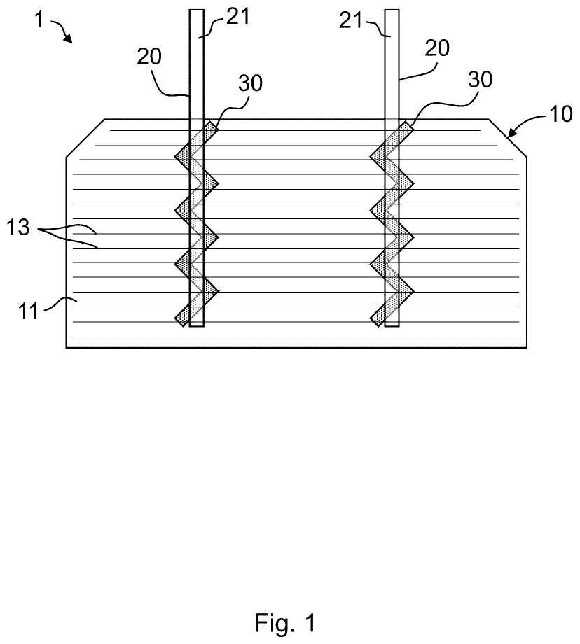

FIG. 1 represents schematically and partially, in a top view, an assembly 1 according to an embodiment of the invention.

As a general rule, such an assembly 1 comprises:
a photovoltaic cell 10,
one or more interconnection strips 20 intended to electrically and mechanically connect the photovoltaic cell 10 to another photovoltaic cell with a view to forming a string of photovoltaic cells, and
one or more lines of electrically conductive adhesive 30 each electrically and mechanically connecting an interconnection strip 20 on the photovoltaic cell 10.

The assembly 1 according to the invention is thus intended to be connected electrically and mechanically to a photovoltaic cell, via one or more interconnection strips 20, with a view to forming a string of photovoltaic cells.

The photovoltaic cell 10 comprises a general plate shape with a front face 11 and a rear face (not shown) opposite the front face. The photovoltaic cell 10 comprises here on its front face 11 a grid contact 13 adapted to collect photogenerated charges. Obviously, the photovoltaic cell may also include a collecting grid on its rear face.

The collecting grid 13 is generally obtained by screen printing a silver, copper and/or aluminum paste or any other type of base on the front face 11 of the photovoltaic cell 10. The collecting grid 13 is here formed from a succession of parallel collecting lines spaced 20 apart from each other. Optionally, the collecting grid may further include a so-called busbar conductive strip, disposed so as to electrically connect the contact lines to each other. In this scenario, the busbar conductive strip preferably extends perpendicularly to the collecting lines.

As a general rule, the interconnection strip 20 has an overall planar and elongated shape. It is made of an electrically conductive material, preferably of copper with a silver coating. It may be made from other materials.

The interconnection strip 20 is disposed on the front face 11 of the photovoltaic cell 10 so as to be connected to several collecting lines, or, in the case where the collecting grid includes a busbar conductive strip, so as to be aligned with the latter. The strip has a length, along a longitudinal axis, which may vary according to the dimensions of the photovoltaic cell, and a width, along a transverse axis perpendicular to the longitudinal axis, which may be between 0.2 mm and 1.2 mm.

The interconnection strip 20 may include a free portion 21 which is not superimposed on the photovoltaic cell 10. The benefit of having a free portion 21 of the interconnection strip 20 is that of facilitating the interconnection of the photovoltaic cells 20.

For example, the free portion 21 is comprised in the same plane as the rest of the interconnection strip 20, which is thus adapted to connect the front face 11 of the photovoltaic cell 10 to a face, generally rear, of another photovoltaic cell located in the same plane as the front face 11. This is referred to as a monolithic interconnection architecture. Alternatively, the free portion 21 is comprised in a separate plane from the rest of the interconnection strip, which is then adapted to connect the front face 11 of the photovoltaic cell to a face, generally rear, of another photovoltaic cell located in a separate plane from the front face 11. This is referred to as a standard interconnection architecture.

As a general rule, the line of adhesive 30, made of an electrically conductive material, is disposed between the front face 11 of the photovoltaic cell 10 and the interconnection strip 20. It extends here so as to be connected to several collecting lines 13 of the photovoltaic cell, and extends preferably perpendicularly to the latter.

The electrically conductive adhesive may for example be chosen from among adhesives comprising conductive particles, for example silver and/or copper particles, carbon nanotubes or silver nanowires, or a polymer matrix, for example of acrylate, epoxy or silicone type. The electrically conductive adhesive 30 advantageously has a cross-linking temperature between 160 and 180° C.

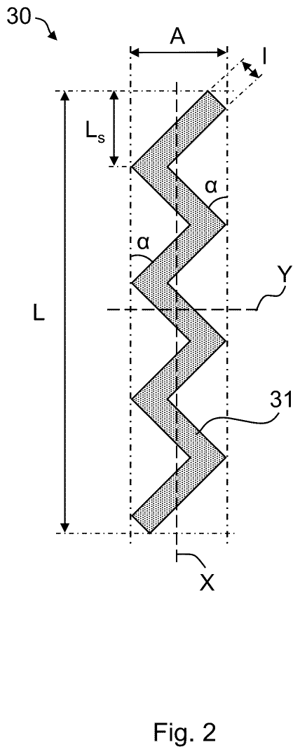

FIG. 2 represents the line of adhesive 30 considered separately. The line of adhesive 30 has a main longitudinal axis X and a transverse axis Y perpendicular to the main longitudinal axis X.

The line of adhesive 30 is arranged according to a zigzag pattern formed from a plurality of segments 31 each forming an angle a with the main longitudinal axis X. Zigzag pattern or line means a broken line forming alternating salient and reentrant angles.

The line of adhesive 30 has a relative length L, defined along the main longitudinal axis X, and an amplitude A of variation (or relative width) defined along the transverse axis Y. The relative length L, or total projected length, corresponds to the sum of the length Ls of the segments 31 defined along the main longitudinal axis X. The length Ls, or projected elementary length, corresponds to the length of the segments 31 projected along the axis X. The amplitude of variation A corresponds to the deviation, along the transverse axis 31, between the opposite vertices of the segments 31. Preferably, the amplitude A is constant along the main longitudinal axis X.

The line of adhesive 30 has a width l, corresponding to the width of the segments 31, that is substantially constant. The amplitude A of variation of the line of adhesive 30 is greater than the width l.

The line of adhesive 30 thus has a surface area S_{zz}, which is expressed literally as:

$${S}_{zz} = n \times L s \times l \qquad ( 1 )$$

where n is the number of segments 31, Ls the projected length of a segment 31, l being the width of the line of adhesive 30.

This surface area S_{zz} may also be expressed as:

$${S}_{zz} = \frac{L \times l}{cos α} \qquad ( 2 )$$

This surface area S_{zz} tends toward a minimum value L×l when the angle α tends toward zero (corresponding to a thin straight line), but it tends toward a maximum value L×A when the angle tends toward 90° (corresponding to a wide straight line).

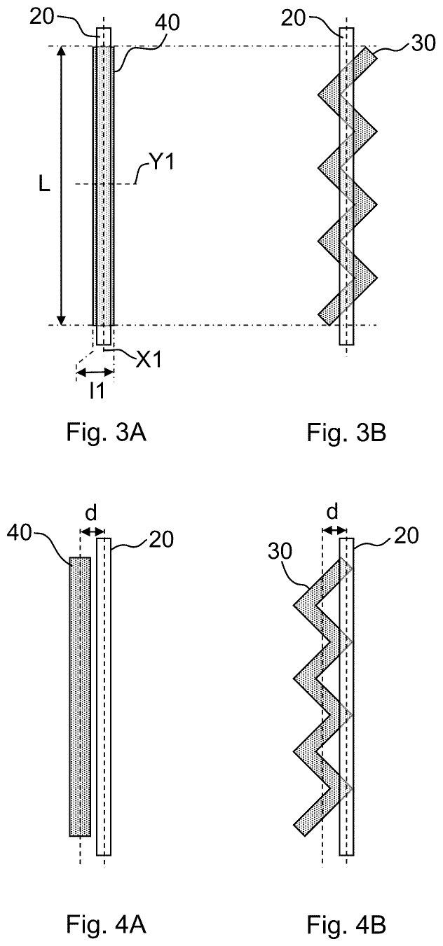

FIGS. 3A and 4A show an interconnection strip 20 disposed on a thin straight line of adhesive 40 with no misalignment (FIG. 3A) and with a misalignment (FIG. 4A).

The thin straight line of adhesive 40 has a length L along a longitudinal axis X1, and a width l1 along a transverse axis Y1 perpendicular to the longitudinal axis X1. The width l1 of the line of adhesive 40 is here chosen substantially equal to the width lr of the interconnection strip 20 (here slightly greater). It should be noted that the thin straight line of adhesive 40 corresponds to a solution of the prior art described above.

With reference to FIG. 3A, it is apparent that, when the interconnection strip 20 and the thin straight line of adhesive 40 are aligned, the contact surface area Sc₁ between the line of adhesive 40 and the strip 20 is maximum: Sc_{1,max}=L×lr.

With reference to FIG. 4A, it is also apparent that, when the interconnection strip 20 and the thin straight line of adhesive 40 are offset, the contact surface area Sc₁ between the line of adhesive 40 and the interconnection strip 20 is reduced, or even may become zero (as illustrated here). The adhesion of the strip 20 on the photovoltaic cell is thus degraded. The lateral offset corresponds here to a misalignment of the strip 20 with respect to the line of adhesive 40 along the transverse axis.

In addition, the contact surface area Sc₁ becomes zero when the lateral offset d between the interconnection strip 20 and the line of adhesive 40 reaches a critical offset threshold dₜₕ, corresponding to the sum of half of the width lr of the interconnection strip 20 and half the width l1 of the line of adhesive 40: dₜₕ=lr/2+l1/2.

FIGS. 3B and 4B show the interconnection strip disposed on the zigzagged line of adhesive 30 with no misalignment (FIG. 3B) and with a misalignment (FIG. 4B). It should be noted that the misalignment is the same in FIGS. 4A and 4B.

To facilitate the comparison with the thin straight line of adhesive 40, the width l of the zigzagged line of adhesive 30 is equal to the width l1 of the thin straight line of adhesive 40. The zigzagged line of adhesive 30 and the thin straight line of adhesive 40 are also considered to have an identical thickness.

With reference to FIGS. 3A and 3B, it is apparent that, when the interconnection strip 20 and the zigzagged line of adhesive 30 are aligned, the contact surface area Sc_{zz} between the zigzagged line of adhesive 30 and the interconnection strip 20 is less than the contact surface area Sc₁ between the thin straight line of adhesive 40 and the interconnection strip 20.

With reference to FIGS. 4A and 4B, it is apparent on the other hand that, when the interconnection strip 20 and the zigzagged line of adhesive 30 are offset beyond the critical offset threshold dₜₕ, the contact surface area Sc_{zz} between the zigzagged line of adhesive 30 and the interconnection strip 20 may be different from zero while the contact surface area Sc₁ between the thin straight line of adhesive 40 and the interconnection strip 20 is zero.

Furthermore, it is apparent that, as the misalignment d increases and exceeds a threshold value, the contact surface area Sc_{zz} between the zigzagged line of adhesive 30 and the interconnection strip 20 becomes greater than the contact surface area Sc₁ between the thin straight line of adhesive 40 and the interconnection strip 20. Indeed, the zigzagged line of adhesive 30 extends on a dimension along the transverse axis Y, namely the amplitude A of variation, which is greater than the dimension along the transverse axis Y1, namely the width l1, on which the thin straight line of adhesive 40 extends. In fact, the zigzagged line of adhesive 30 makes it possible to improve the adhesion of the interconnection strip 20 on the photovoltaic cell in the presence of a misalignment d between the interconnection strip and the line of adhesive 30, while, for an equivalent misalignment, the adhesion of the interconnection strip 20 via a straight line of adhesive of the same width may be degraded.

The surface area S of the zigzagged line of adhesive 30 is however greater than a surface area S1 of the straight and thin line of adhesive 40. Indeed, the surface area of the thin straight line of adhesive 30, is expressed literally as:

$$S 1 = L \times l 1 \qquad ( 3 )$$

Taking equation (2), the ratio ΔS between the surface area S1 of the thin straight line of adhesive 40 and the surface area S of the zigzagged line of adhesive 30 is written as:

$$Δ S = \frac{\frac{L \times l}{cos α}}{L \times l 1} \qquad ( 4 )$$

When the width l of the zigzagged line of adhesive 30 and the width l1 of the thin straight line of adhesive 40 are equal, this gives:

$$Δ S = \frac{1}{cos α} \qquad ( 5 )$$

Thus in this case, the surface area (and therefore adhesive overconsumption) ratio ΔS between the zigzagged line of adhesive 30 and the thin straight line of adhesive 40 is only determined by the angle α formed by the segments 31 with the main longitudinal axis X. The angle α is therefore determined so as to improve the adhesion of the strip on the photovoltaic cell in the presence of a lateral offset while limiting adhesive overconsumption.

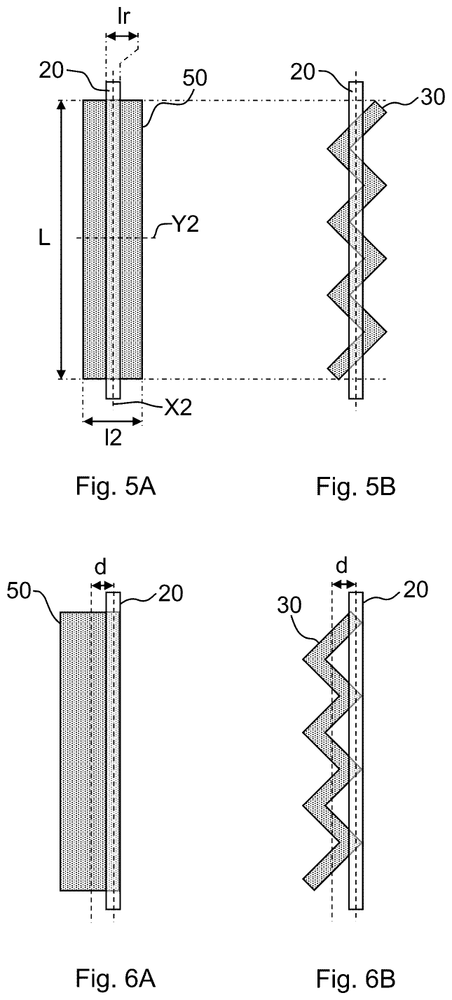

FIGS. 5A and 6A show an interconnection strip 20 disposed on a wide straight line of adhesive 40 with no misalignment (FIG. 5A) and with a misalignment (FIG. 6A).

The wide straight line of adhesive 50 has a length L along a main longitudinal axis X2, and a width l2 along a transverse axis Y2 perpendicular to the longitudinal axis X2. The width l2 of the wide straight line of adhesive 50 is greater than the width l1 of the thin straight line of adhesive 40.

The width l2 of the wide straight line of adhesive 50 is such that, in the presence of a misalignment d2 equal to the misalignment d1 of FIGS. 3B and 4B, the contact surface area Sc2 between the line of adhesive 50 and the interconnection strip 20 is maximum: Sc2ₘₐₓ=L×lr. The width l2 is equal to three times the width l1 of the thin straight line of adhesive 40.

The wide straight line of adhesive 50 thus has a surface area S2 which is three times greater than the surface area S1 of the thin straight line of adhesive 40. This represents an additional adhesive consumption of 200% for the same thickness.

FIGS. 5B and 6B are similar to FIGS. 3B and 4B. They make it possible to illustrate the comparison between the zigzagged line of adhesive 30 and the wide straight line of adhesive 50. To facilitate this comparison, the amplitude A of variation of the zigzagged line of adhesive 30 is equal to the width l2 of the wide straight line of adhesive 50. The zigzagged line of adhesive 30 and the wide straight line of adhesive 50 are also considered to have an identical thickness.

With reference to FIG. 5A to 6B, it is apparent that the contact surface area Sc_{zz} between the zigzagged line of adhesive 30 and the interconnection strip 20 is less than the contact surface area Sc2 between the wide straight line of adhesive 50 and the interconnection strip 20, with and without misalignment.

It is worth noting, as stated above, that when the angle a formed by the segments 31 with the main longitudinal axis X tends toward 90°, the surface area S_{zz} of the zigzagged line of adhesive 30 tends to move closer to the surface area S2 of the wide straight line of adhesive 50.

In addition, by increasing the value of the angle α, the adhesion of the interconnection strip on the cell is improved, but the adhesive consumption is increased. It is however observed that when the angle α is greater than 30°, the improvement in the adhesion is not significant relative to the increase in the adhesive overconsumption. In other words, it was observed that a value of the angle a less than or equal to 30° represents an advantageous compromise between adhesion and adhesive overconsumption.

Taking equation (5), it is observed that the additional adhesive consumption, relative to the thin straight line, when the angle α is equal to 30° is 15.5%.

Furthermore, it was observed that when the angle α is greater than 15°, the adhesion is significantly improved. Thus, preferably, the angle α is between 15° and 30°.

The zigzagged line of adhesive makes it possible, thanks to its amplitude which is greater than its width, to improve the adhesion of the strip on the photovoltaic cell in the case of misalignment of the strip and the line of adhesive relative to a straight line of adhesive of the same width. By limiting the value of the angle formed by the segments and the main longitudinal axis to 30°, it is possible to limit the additional adhesive consumption to 15.5% relative to a straight line of adhesive of the same width. Furthermore, this also makes it possible to reduce the adhesive consumption relative to a continuous straight line having a width equal to the amplitude of variation of the zigzagged line of adhesive.

Thus, the zigzagged line of adhesive makes it possible to improve the adhesion of the strip on the photovoltaic cell in the case of misalignment between the strip and the line of adhesive, while limiting the adhesive consumption.

For example, in the case of a straight line of adhesive having a relative length equal to 100 mm and a width equal to 0.3 mm and an interconnection strip having a width equal to 0.6 mm, it is apparent that for a zigzagged line of adhesive having the same relative length and the same width, an amplitude of 0.5 mm and an angle ranging from 5° to 10° allowing an improvement of the contact surface area for substantial offsets, for example by 0.4 mm, between the interconnection strip and the line of adhesive. The improvement is 40% for an angle of 10° and 74% for an angle of 5°. Moreover, the angle of 10° makes it possible to limit adhesive overconsumption to 1.5% relative to the straight line of adhesive, whereas the angle of 5% makes it possible to limit overconsumption to 0.4%.

For an angle ranging from 15° to 30°, it is apparent that the zigzagged line of adhesive allows an improvement of the contact surface area for smaller offsets, for example by 0.3 mm, between the interconnection strip and the line of adhesive. The improvement is 33% for an angle of 30° when the offset is 0.3 mm. The improvement is 20% for an angle of 15° and 200% for an angle of 30° when the offset is 0.4 mm. Moreover, the angle of 30° makes it possible to limit adhesive overconsumption to 15.5% relative to the straight line of adhesive, whereas the angle of 15% makes it possible to limit overconsumption to 3.5%.

For example, the photovoltaic cell may be of the half M2 type, i.e. having a rectangular shape having a length approximately equal to 78 mm and a width approximately equal to 156 mm.

In this case, the assembly may comprise a plurality of lines of adhesive. The number of lines may be between 4 and 20 and preferably between 6 and 9. In the case where the collecting grid comprises one or more conductive strips, the assembly may comprise the same number of lines of adhesive as conductive strips.

Each line of adhesive may for example have an amplitude between 0.1 mm and 1.5 mm, a width between 0.1 mm and 1.2 mm, preferably between 0.3 mm and 0.8 mm, and a length which is less than or equal to the length of the photovoltaic cell, which is here equal to 78 mm. The number of segments is for example between 3 and 21, and more particularly between 13 and 16.

The assembly may also comprise a plurality of interconnection strips. Each strip may have a width between 0.2 mm and 1.2 mm, preferably between 0.4 mm and 0.8 mm, and a thickness between 0.1 and 0.4 mm.

The method for manufacturing such an assembly 1 thus includes a step of producing a photovoltaic cell similar to that described with reference to FIG. 1, and a step of producing an interconnection strip similar to that described with reference to FIG. 1.

The method then includes a step of depositing a line of electrically conductive adhesive on a face, for example front and/or rear, of the cell. The line of adhesive is disposed so as to intercept, preferably perpendicularly, collecting lines of the cell. The line of adhesive is deposited so as to define a zigzagged pattern formed from a plurality of segments each forming an angle less than 30° with the main longitudinal axis of the line of adhesive, and having an amplitude of variation, along the transverse axis, which is less than the width of the line of adhesive and which, preferably, is between 0.5 and 1.5 times the width of the interconnection strip.

The method then includes a step of depositing the interconnection strip on the face of the cell, in contact with the line of adhesive.

An assembly 1 is thus obtained wherein the adhesion of the interconnection strip is improved in the case of misalignment of the strip and the line of electrically conductive adhesive, and wherein the adhesive consumption is limited.

1. An assembly comprising:
at least one photovoltaic cell comprising a face on which a collecting grid is arranged,
at least one interconnection strip attached to said face, said interconnection strip being intended to electrically and mechanically connect the photovoltaic cell to another photovoltaic cell, and
at least one line of adhesive, made of an electrically conductive material, disposed between the collecting grid and the interconnection strip, the line of adhesive being adapted to mechanically and electrically connect the interconnection strip to the photovoltaic cell, the line of adhesive extending substantially along a main longitudinal axis (X) and having a substantially constant width,
wherein the line of adhesive is disposed according to a zigzag pattern formed from a plurality of segments each forming an angle (α) less than or equal to 30° with the main longitudinal axis (X), and with an amplitude (A) of variation, along a transverse axis (Y) perpendicular to the main longitudinal axis (X), which is greater than the width of the line of adhesive.

2. The assembly according to claim 1, wherein the angle (α) formed by the segments with the main longitudinal axis (X) is between 15° and 30°.

3. The assembly according to claim 1, wherein a ratio between the amplitude (A) of variation of the line of adhesive and a width of the interconnection strip is between 0.5 and 1.5.

4. The assembly according to claim 3, wherein the width of the interconnection strip is between 0.2 mm and 1.2 mm.

5. The assembly according to claim 1, wherein the line of electrically conductive adhesive is made of a material chosen from among adhesives comprising conductive particles, for example silver and/or copper particles, carbon nanotubes or silver nanowires, or a polymer matrix, for example of acrylate, epoxy or silicone type.
